(19) United States
(12) Patent Application Publication
(10) Pub. No.: US 2026/0290765 A1
(43) Pub. Date: Sep. 24, 2026

(54) CLEANING METHOD AND PLASMA PROCESSING APPARATUS

(71) Applicant: Tokyo Electron Limited, Tokyo (JP)

(72) Inventors: Takafumi NOGAMI, Yamanashi (JP); Yoshiki NAKANO, Yamanashi (JP); Kenichi KOTE, Yamanashi (JP)

(21) Appl. No.: 19/566,335

(22) Filed: Mar. 13, 2026

(30) Foreign Application Priority Data
Mar. 18, 2025 (JP) 2025-043796

(51) Int. Cl. H01J 37/32

(52) U.S. Cl. CPC H01J 37/32862; H01J 37/32201; H01J 37/32449

(57) ABSTRACT

A cleaning method includes supplying a cleaning gas into a processing chamber from a plurality of first gas nozzles provided through a top plate and each having a first nozzle diameter, supplying a diluent gas into the processing chamber from a plurality of second gas nozzles provided through the top plate and each having a second nozzle diameter larger than the first nozzle diameter, generating plasma from the cleaning gas and the diluent gas supplied into the processing chamber; and performing cleaning by exposing an interior of the processing chamber to the plasma.

### CROSS-REFERENCE TO RELATED APPLICATIONS

This application is based on and claims priority to Japanese Patent Application No. 2025-043796, filed on Mar. 18, 2025, the entire contents of which are incorporated herein by reference.

### TECHNICAL FIELD

The present disclosure relates to a cleaning method and a plasma processing apparatus.

### BACKGROUND ART

Japanese Laid-Open Patent Publication No. 2022-151131 describes a technique by which the interior of a processing chamber is cleaned by using microwaves to generate plasma in the processing chamber.

### SUMMARY

A cleaning method according to one aspect of the present disclosure includes supplying a cleaning gas into a processing chamber from a plurality of first gas nozzles provided through a top plate and each having a first nozzle diameter, supplying a diluent gas into the processing chamber from a plurality of second gas nozzles provided through the top plate and each having a second nozzle diameter larger than the first nozzle diameter, generating plasma from the cleaning gas and the diluent gas supplied into the processing chamber; and performing cleaning by exposing an interior of the processing chamber to the plasma.

### BRIEF DESCRIPTION OF THE DRAWINGS

FIG. 1 is a schematic cross-sectional view illustrating a plasma processing apparatus according to an embodiment;

FIG. 2 is a schematic plan view illustrating a top plate of the plasma processing apparatus according to the embodiment;

FIG. 3 is an enlarged view of a region A1 of FIG. 1;

FIG. 4 is a flowchart illustrating a substrate processing method according to the embodiment;

FIG. 5 is a graph illustrating the relationship between the nozzle diameter of a gas nozzle and the flow velocity of gas;

FIG. 6 is a diagram (1) illustrating gas flows during a cleaning process;

FIG. 7 is a diagram (2) illustrating gas flows during the cleaning process;

FIG. 8 is a graph illustrating the dependency of the number of particles on the number of processed substrates in an Example; and

FIG. 9 is a graph illustrating the dependency of the number of particles on the number of processed substrates in a Comparative Example.

### DETAILED DESCRIPTION

Non-limiting exemplary embodiments of the present disclosure will be described below with reference to the accompanying drawings. In all of the accompanying drawings, the same or corresponding members or components are denoted by the same or corresponding reference numerals, and duplicated descriptions will be omitted.

### Plasma Processing Apparatus

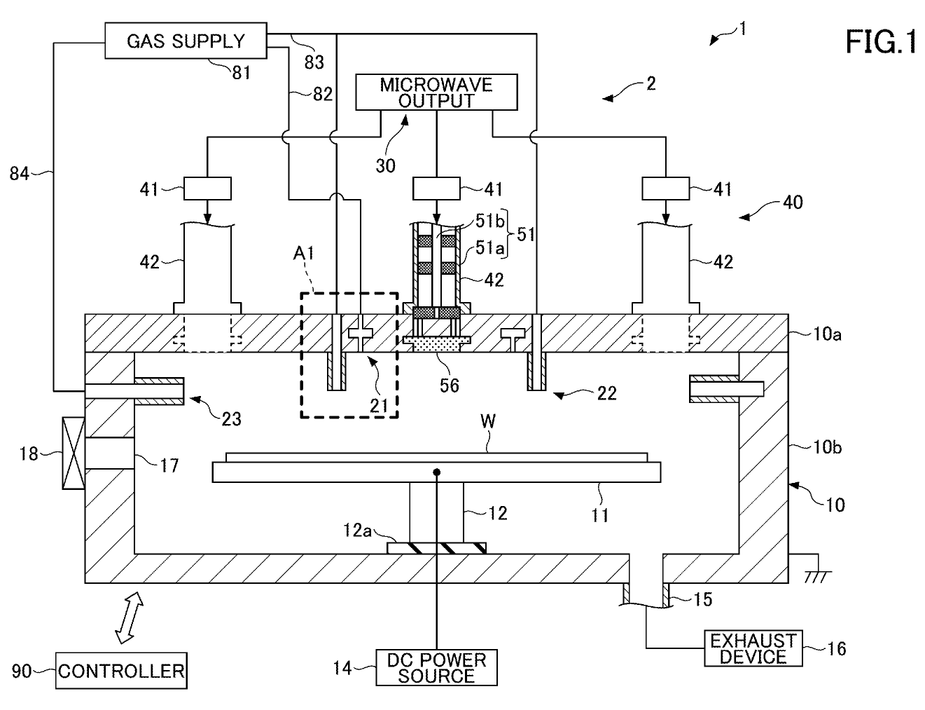

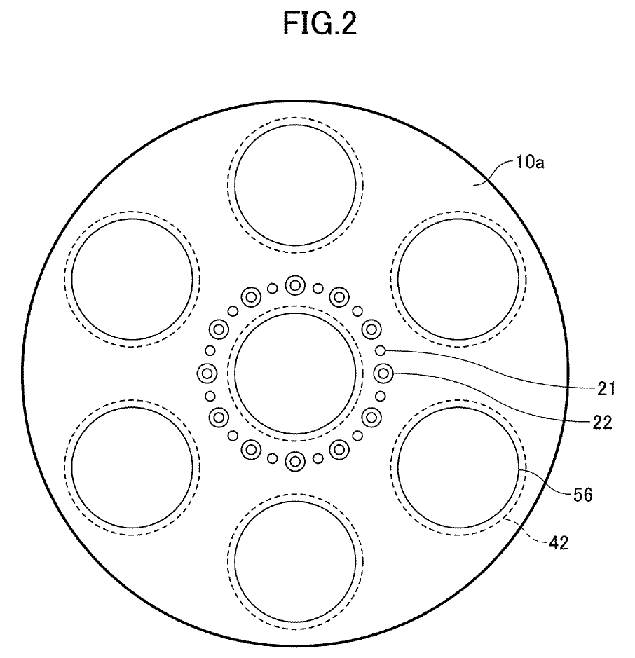

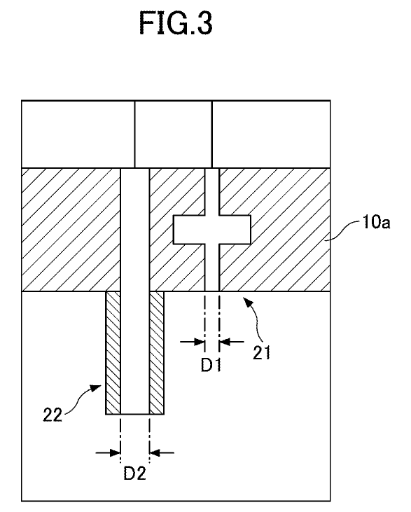

A plasma processing apparatus 1 according to an embodiment will be described with reference to FIGS. 1-3. FIG. 1 is a schematic cross-sectional view illustrating the plasma processing apparatus 1 according to the embodiment. FIG. 2 is a schematic plan view illustrating a top plate 10a of the plasma processing apparatus 1 according to the embodiment. FIG. 3 is an enlarged view of a region A1 of FIG. 1.

The plasma processing apparatus 1 is an apparatus configured to generate microwave plasma. The plasma processing apparatus 1 includes a processing chamber 10 and a plasma source 2. The processing chamber 10 has a substantially cylindrical shape. The processing chamber 10 is grounded. The processing chamber 10 is configured to be airtight and is formed of a metal material such as aluminum. A surface of the top plate 10a in the processing chamber 10 is covered with a thermally sprayed film. The thermally sprayed film is formed of a material having plasma resistance. The material having plasma resistance may be a ceramic material such as yttria (Y₂O₃). The thermally sprayed film protects the surface of the top plate 10a in the processing chamber 10 from plasma during plasma processing, and reduces generation of particles caused by the metal material such as aluminum forming the top plate 10a.

The plasma source 2 introduces microwaves of a predetermined power into the processing chamber 10 to form surface wave plasma. The top plate 10a of the processing chamber 10 is configured with a main body made of a metal into which dielectric members (hereinafter referred to as dielectric windows 56) of a plurality of microwave radiation mechanisms 42 are fitted. Thus, the plasma source 2 introduces microwaves into the processing chamber 10 via the plurality of dielectric windows 56 in the top plate 10a.

The plasma processing apparatus 1 includes a controller 90. The controller 90 is an electronic circuit such as a central processing unit (CPU), a field programmable gate array (FPGA), or an application specific integrated circuit (ASIC). The controller 90 performs various control operations described in the present specification by executing instruction codes stored in a memory or by being designed as a circuit for a special application.

In the processing chamber 10, a stage 11 is supported at the center of the bottom of the processing chamber 10 by a cylindrical support member 12 via an insulating member 12a. The stage 11 supports a substrate W horizontally. Examples of materials used for the stage 11 and the support member 12 include a metal such as aluminum whose surface is subjected to anodization (anodic oxidation), and an insulating material (such as a ceramic) having therein an electrode for high-frequency radiation.

The stage 11 is provided with a temperature control mechanism, a gas flow path for supplying gas for heat transfer to the back surface of the substrate W, pins for moving the substrate W up and down, and the like. The stage 11 may be provided with an electrostatic chuck for electrostatically attracting the substrate W.

A DC power source 14 is connected to the stage 11. By supplying a DC voltage from the DC power source 14 to the stage 11, ions in plasma are drawn toward the substrate W, thereby contributing to the improvement of film quality and in-plane uniformity of substrate W processing. A high-frequency power source may be connected instead of the DC power source 14. The DC power source 14 and the high-frequency power source are not necessarily connected.

An exhaust pipe 15 is connected to the bottom of the processing chamber 10. An exhaust device 16 including a vacuum pump is connected to the exhaust pipe 15. By operating the exhaust device 16, the interior of the processing chamber 10 can be evacuated, and the pressure in the processing chamber 10 can be reduced to a predetermined pressure. A side wall 10b of the processing chamber 10 is provided with a loading/unloading port 17 for loading and unloading the substrate W, and a gate valve 18 for opening and closing the loading/unloading port 17.

The plasma processing apparatus 1 includes a first gas nozzle 21, a second gas nozzle 22, and a third gas nozzle 23. The first gas nozzle 21 discharges a predetermined gas from the top plate 10a of the processing chamber 10 into the processing chamber 10. The second gas nozzle 22 introduces gas from a position located between the top plate 10a and the stage 11. The third gas nozzle 23 introduces gas from a position located between the top plate 10a and the stage 11 and outward of the second gas nozzle 22 in the processing chamber 10. Although the first gas nozzle 21 and the second gas nozzle 22 are illustrated at positions shifted in the radial direction in FIG. 1 for the sake of convenience, the first gas nozzle 21 and the second gas nozzle 22 are alternately arranged on the same circle as illustrated in FIG. 2. In the example of FIG. 2, twelve first gas nozzles 21 and twelve second gas nozzles 22 are alternately arranged on the same circle.

The first gas nozzle 21 is provided through the top plate 10a of the processing chamber 10. The first gas nozzle 21 supplies, from a first position, gas conveyed from a gas supply 81 through a gas line 82. The first gas nozzle 21 supplies the gas, for example, vertically downward. The first gas nozzle 21 has a first nozzle diameter D1 (see FIG. 3). The first nozzle diameter D1 may be 0.3 mm or less, and is, for example, 0.3 mm.

The second gas nozzle 22 is provided through the top plate 10a of the processing chamber 10. The second gas nozzle 22 supplies, from a second position lower than the first position, gas conveyed from the gas supply 81 through a gas line 83. The second gas nozzle 22 supplies the gas, for example, vertically downward. The second gas nozzle 22 has a second nozzle diameter D2 (see FIG. 3). The second nozzle diameter D2 is larger than the first nozzle diameter D1. The second nozzle diameter D2 may be 0.5 mm or more and 2.0 mm or less, and is, for example, 0.5 mm.

The third gas nozzle 23 is provided through the side wall 10b of the processing chamber 10. The third gas nozzle 23 supplies, from a third position lower than the first position, gas conveyed from the gas supply 81 through a gas line 84. The third gas nozzle 23 supplies the gas, for example, horizontally.

When a film forming process of a substrate processing method described later is performed, a silicon source gas may be supplied from the second gas nozzle 22 and the third gas nozzle 23. Examples of the silicon source gas include monosilane (SiH₄) gas, disilane (Si₂H₆) gas, dichlorosilane (DCS) gas, deuterated silane (SiD₄) gas, or a combination thereof. A reactive gas (nitride gas) may be supplied from the first gas nozzle 21, the second gas nozzle 22, and the third gas nozzle 23. Examples of the nitride gas include nitrogen (N₂) gas, ammonia (NH₃) gas, a mixed gas of nitrogen gas and hydrogen (H₂) gas, or a combination thereof. The silicon source gas may be supplied from at least one of the second gas nozzle 22 or the third gas nozzle 23. By supplying the silicon source gas from the second position and/or the third position lower than the first position of the first gas nozzle 21, excessive dissociation of the silicon source gas can be suppressed.

When a cleaning process of the substrate processing method described later is performed, a cleaning gas may be supplied from the first gas nozzle 21 and a diluent gas may be supplied from the second gas nozzle 22. The diluent gas functions as a plasma generation gas (ignition gas). The cleaning gas includes, for example, a halogen-containing gas. Examples of the halogen-containing gas include nitrogen trifluoride (NF₃) gas, chlorine trifluoride (ClF₃) gas, sulfur hexafluoride (SF₆) gas, tetrafluoromethane (CF₄) gas, or a combination thereof. Examples of the diluent gas include argon (Ar) gas, helium (He) gas, nitrogen gas, or a combination thereof. The diluent gas may be supplied from the first gas nozzle 21 or the third gas nozzle 23, or may be supplied from one or more of the first gas nozzle 21, the second gas nozzle 22, and the third gas nozzle 23.

The plasma source 2 includes a microwave output 30 that outputs microwaves by distributing them to a plurality of paths, and a microwave transmitter 40 that transmits the microwaves output from the microwave output 30.

The microwave output 30 includes a microwave power source, a microwave oscillator, an amplifier, and a distributor. The microwave power source supplies power to the microwave oscillator. The microwave oscillator causes, for example, PLL oscillation of microwaves at a predetermined frequency (for example, 860 MHz). The amplifier amplifies the oscillated microwaves. The distributor distributes the microwaves amplified by the amplifier while maintaining impedance matching on both the input and output sides so as to minimize the loss of the microwaves. In addition to 860 MHz, various frequencies ranging from 700 MHz to 3 GHz, such as 915 MHz, may be used as the frequency of the microwaves.

The microwave transmitter 40 includes a plurality of amplifier parts 41 and the plurality of microwave radiation mechanisms 42 provided corresponding to the amplifier parts 41. For example, a total of seven microwave radiation mechanisms 42 are provided, that is, one at the center of the top plate 10a and six at equal intervals on a circumference centered on the center one. In this example, the plurality of microwave radiation mechanisms 42 are arranged such that the distance between the center microwave radiation mechanism 42 and each of the peripheral microwave radiation mechanisms 42 is equal to the distance between adjacent peripheral microwave radiation mechanisms 42.

The amplifier parts 41 amplify the microwaves distributed by the distributor and guide the microwaves to the microwave radiation mechanisms 42. Each of the microwave radiation mechanisms 42 includes a coaxial tube 51. The coaxial tube 51 includes a coaxial microwave transmission path consisting of a cylindrical outer conductor 51a and a rod-shaped inner conductor 51b provided at the center of the outer conductor 51a. Each of the microwave radiation mechanisms 42 includes a feeding antenna (not illustrated) for feeding microwaves amplified by a corresponding one of the amplifier parts 41 to the coaxial tube 51. Each of the microwave radiation mechanisms 42 includes a tuner for matching the impedance of the load with the characteristic impedance of the microwave power source, and an antenna part for radiating the microwaves from the coaxial tube into the processing chamber 10.

The antenna part is provided at the lower end of the coaxial tube 51 and is fitted into a metal portion of the top plate 10a of the processing chamber 10. The antenna part includes a dielectric window 56. Surface wave plasma is generated in a portion directly under the dielectric window 56 in the processing chamber 10 by the microwaves transmitted through the dielectric window 56.

A plurality of plasma sources 2 (dielectric windows 56) are provided, that is, one at the center of the ceiling and six at the outer periphery. The plurality of plasma sources 2 (dielectric windows 56) can independently control microwave power supplied from the plasma sources 2 themselves. Microwave power supplied from the plasma sources 2 (the dielectric windows 56) at the outer periphery may be higher than, lower than, or equal to microwave power supplied from the plasma source 2 at the center.

### Substrate Processing Method

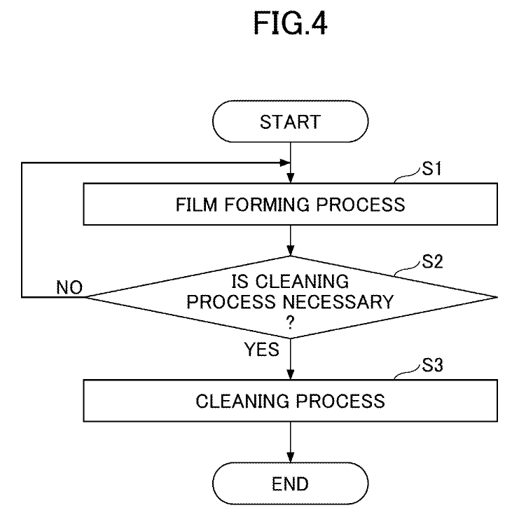

The substrate processing method according to the embodiment will be described with reference to FIGS. 4-7. FIG. 4 is a flowchart illustrating the substrate processing method according to the embodiment. The substrate processing method according to the embodiment includes steps S1 to S3 illustrated in FIG. 4.

In step S1, the controller 90 performs the film forming process. In the film forming process, the controller 90 supplies microwaves of a first power into the processing chamber 10 in a state in which the substrate W is placed on the stage 11, and performs control such that a first film is formed on the substrate W by plasma generated from a film forming gas using the microwaves of the first power. The film forming gas may contain the silicon source gas and a nitrogen-containing gas. In this case, a silicon nitride film can be formed as the first film. The silicon source gas may be supplied from at least one of the second gas nozzle 22 or the third gas nozzle 23. By supplying the silicon source gas from the second position and/or the third position lower than the first position of the first gas nozzle 21, excessive dissociation of the silicon source gas can be reduced. The nitrogen-containing gas may be supplied from at least one of the first gas nozzle 21, the second gas nozzle 22, or the third gas nozzle 23.

When the film forming process is performed in step S1, deposits are accumulated on the surface of a structure in the processing chamber 10, such as an inner wall surface in the processing chamber 10. Therefore, in step S2, the controller 90 determines whether the cleaning process is necessary. That is, the controller 90 determines whether the cleaning process is necessary each time the film forming process is performed in step S1. For example, if the number of substrates W subjected to the film forming process reaches a predetermined number, the controller 90 determines that the cleaning process is necessary. The controller 90 may determine that the cleaning process is necessary if the accumulated film thickness by the film forming process reaches a predetermined film thickness. If the controller 90 determines that the cleaning process is necessary in step S2 (YES in step S2), the controller 90 performs the cleaning process in step S3. If the controller 90 determines that the cleaning process is not necessary in step S2 (NO in step S2), the controller 90 performs the film forming process in step S1 again. As described above, the controller 90 performs the cleaning process in step S3 each time the predetermined number of substrates W is processed or each time the accumulated film thickness reaches the predetermined film thickness.

In step S3, the controller 90 performs the cleaning process. In the cleaning process, the controller 90 generates plasma from the cleaning gas and the diluent gas in the processing chamber 10 and performs control such that deposits accumulated on the surface of the structure in the processing chamber 10 are removed by the generated plasma. In this case, a base material (for example, aluminum) of the processing chamber 10 and a protective film (for example, aluminum oxide) on the inner surface of the processing chamber 10 may react with the cleaning gas, reaction by-products may be generated, and the generated reaction by-products may adhere to the inner surface of the processing chamber 10. If such reaction by-products accumulate, they would peel off from the inner surface of the processing chamber 10, resulting in particles. Further, a step would be formed between a portion where the reaction by-products have peeled off and a portion where the reaction by-products have not peeled off, thereby making it difficult to cover the inner surface of the processing chamber 10 with a precoat film. For this reason, if reaction by-products are generated, it would be necessary to replace parts.

In the present embodiment, the controller 90 supplies the cleaning gas from the first gas nozzle 21 into the processing chamber 10, supplies the diluent gas from the second gas nozzle 22 into the processing chamber 10, and supplies microwaves of a second power into the processing chamber 10. In this case, reaction by-products generated during the cleaning process are less likely to adhere to the processing chamber 10, and thus generation of particles can be suppressed. The reasons are considered as follows.

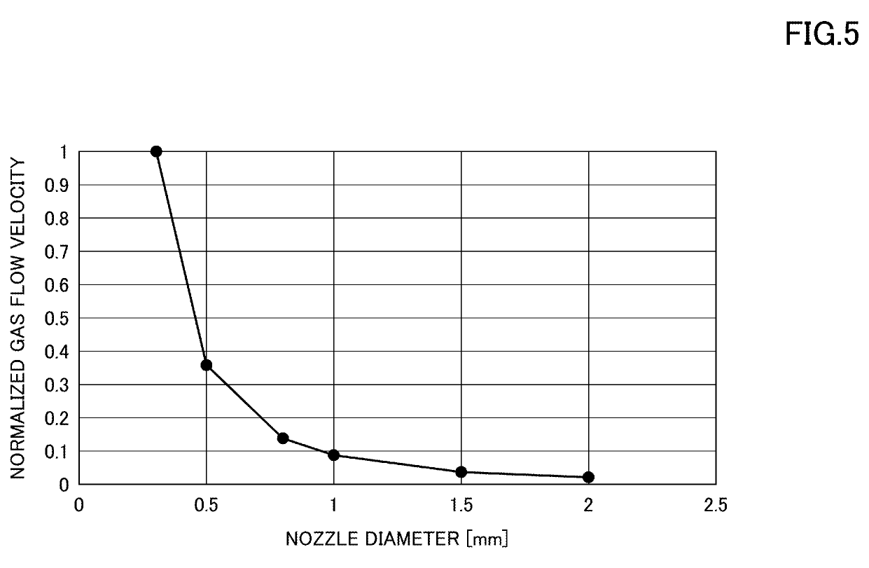

FIG. 5 is a graph illustrating the relationship between the nozzle diameter of a gas nozzle and the flow velocity of gas. In FIG. 5, the horizontal axis represents the nozzle diameter [mm] of the gas nozzle, and the vertical axis represents the normalized flow velocity of the gas at the tip (lower end) position of the gas nozzle. The flow velocity of the gas for each of the nozzle diameters of 0.5 mm, 0.8 mm, 1.0 mm, 1.5 mm, and 2.0 mm is indicated as a relative value, with the flow velocity of the gas for a nozzle diameter of 0.3 mm defined as 1. As illustrated in FIG. 5, it can be seen that the flow velocity of the gas supplied from the gas nozzle decreases as the nozzle diameter of the gas nozzle increases.

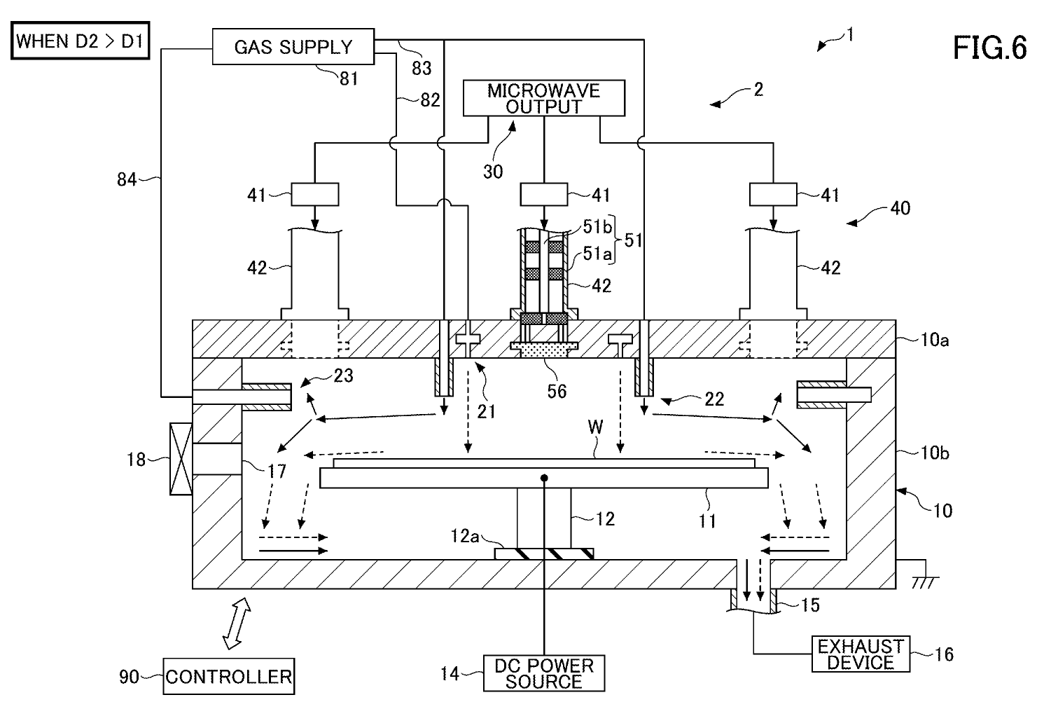

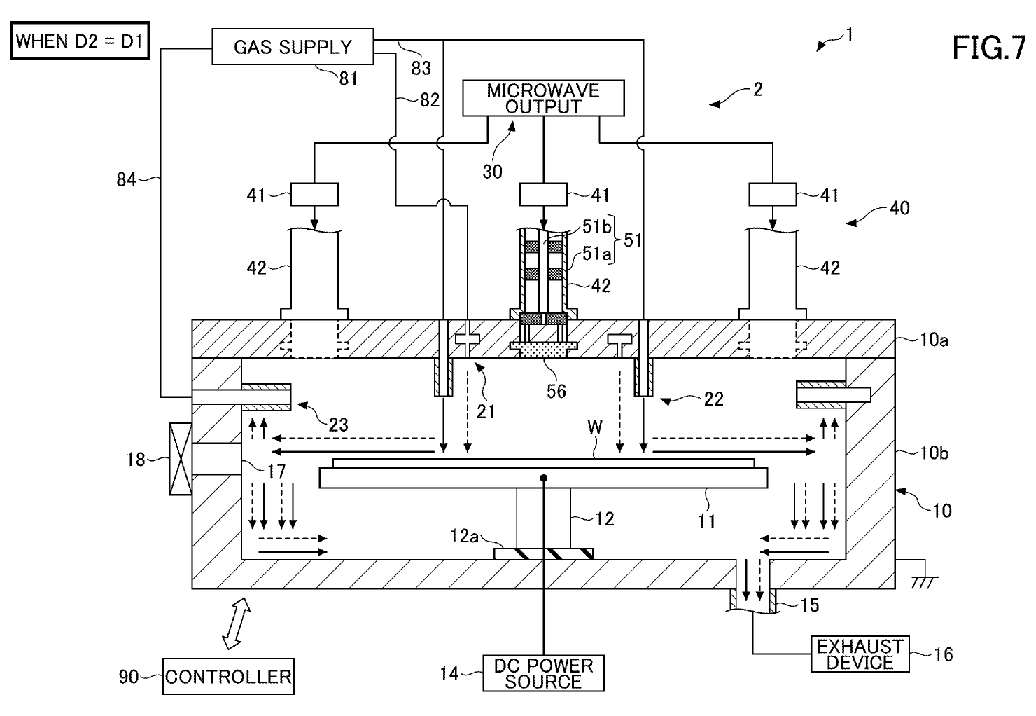

FIGS. 6 and 7 are diagrams illustrating gas flows during the cleaning process. FIG. 6 illustrates the flows of the cleaning gas and the diluent gas when the nozzle diameter D2 of the second gas nozzle 22 is larger than the nozzle diameter D1 of the first gas nozzle 21 (hereinafter also referred to as “D2 > D1”). FIG. 7 illustrates the flows of the cleaning gas and the diluent gas when the nozzle diameter D2 of the second gas nozzle 22 is the same as the nozzle diameter D1 of the first gas nozzle 21 (hereinafter also referred to as “D2 = D1”). In FIGS. 6 and 7, the flow of the cleaning gas is indicated by dashed lines, and the flow of the diluent gas is indicated by solid lines.

As illustrated in FIG. 6, when D2 > D1, the flow velocity of the diluent gas supplied from the second gas nozzle 22 decreases, and therefore the diluent gas tends to form a flow that diffuses toward the side wall 10b of the processing chamber 10 immediately after being supplied from the second gas nozzle 22. The diluent gas that has reached the side wall 10b of the processing chamber 10 forms a downward flow along the side wall 10b. Therefore, reaction by-products generated during the cleaning process are easily pushed downward. For this reason, adhesion of reaction by-products generated during the cleaning process to the interior of the processing chamber 10 can be reduced.

As illustrated in FIG. 7, when D2 = D1, the flow velocity of the diluent gas supplied from the second gas nozzle 22 increases, and therefore the diluent gas tends to flow downward until reaching the upper surface of the stage 11 and then tends to form a flow that spreads toward the side wall 10b of the processing chamber 10. As a result, a downward flow is less likely to be formed in a region of the side wall 10b of the processing chamber 10 located above the upper surface of the stage 11. Therefore, reaction by-products generated during the cleaning process tend to adhere to the interior of the processing chamber 10.

In step S3, the diluent gas may be supplied from the first gas nozzle 21 into the processing chamber 10 together with the cleaning gas.

In step S3, the flow rate of the diluent gas supplied from the second gas nozzle 22 into the processing chamber 10 may be less than or equal to the flow rate of the cleaning gas supplied from the first gas nozzle 21 into the processing chamber 10. In this case, the diluent gas easily forms a flow that diffuses toward the side wall 10b of the processing chamber 10 immediately after the diluent gas is supplied from the second gas nozzle 22. In this case, the ratio of the cleaning gas to the diluent gas can be set, for example, in a range from 1:1 to 5:1 (cleaning gas:diluent gas). In the cleaning process, the total gas flow rate is limited because pressure control is performed so as to achieve a specific pressure. The amount of the cleaning gas introduced correlates with the cleaning rate, and the cleaning rate is saturated when the flow rate of the cleaning gas reaches approximately half of the total gas flow rate. Further, as the ratio of the cleaning gas to the diluent gas is increased, it becomes difficult to maintain plasma. Therefore, from the viewpoint of the cleaning rate and plasma maintenance, the ratio of the cleaning gas to the diluent gas is preferably in the range of 1:1 to 5:1 (cleaning gas:diluent gas).

The first nozzle diameter D1 may be 0.3 mm or less, and is, for example, 0.3 mm. The second nozzle diameter D2 is larger than the first nozzle diameter D1. The second nozzle diameter D2 is preferably 0.5 mm or more. In this case, reaction by-products generated during the cleaning process are less likely to adhere to the interior of the processing chamber 10. The second nozzle diameter D2 is preferably 2.0 mm or less. In this case, the film forming gas is less likely to stagnate near the top plate 10a during the film forming process. Thus, generation of particles originating from the film forming gas can be reduced. The second nozzle diameter D2 is more preferably 1.5 mm or less. In this case, a first film having good in-plane uniformity can be easily formed in the film forming process.

The cleaning process in step S3 may include a plurality of steps in which the pressure in the processing chamber 10, the second power, the temperature of the stage 11, the processing time, or two or more of these process conditions are different.

For example, in a case where the plurality of steps include a first step, a second step, and a third step, which are performed in this order, pressure P1 in the first step, pressure P2 in the second step, and pressure P3 in the third step may satisfy the relation P1 > P2 > P3. In this case, a plasma region can be expanded stepwise so as to expand a cleaning range stepwise from local cleaning to overall cleaning. The pressure P1 in the first step, the pressure P2 in the second step, and the pressure P3 in the third step may satisfy the relation P1 < P2 < P3. In this case, from the viewpoint of the cleaning amount, because the cleaning rate increases as the pressure decreases, products can be removed in a short time when the products thickly adhere to the interior of the processing chamber 10. Further, from the viewpoint of the amount of by-products generated in the cleaning process, generation of by-products can be suppressed by gradually increasing the pressure in the second step and the pressure in the third step to switch to cleaning in which radicals are dominant. The pressure P1, the pressure P2, and the pressure P3 are determined based on, for example, correlation data between the pressure in the processing chamber 10 and the diffusion distance of plasma. The correlation data may be prepared by a preliminary experiment or the like. The first step, the second step, and the third step may be repeated two or more times in this order. For example, in a case where the first step, the second step, and the third step are repeated twice in this order, the pressure is the same between the first step and the second step, and the processing time may be shortened. In this case, in the first step, products adhering to the interior of the processing chamber 10 are removed by cleaning, and in the second step, residues that cannot be removed in the first step are removed by cleaning. Therefore, in the second step, generation of by-products derived from products generated during the cleaning can be suppressed.

Examples of process conditions for the film forming process and for the cleaning process in the above-described substrate processing method are as follows.

### Process Conditions for Film Forming Process

Silicon source gas: Monosilane gas (15 sccm to 130 sccm)

Nitrogen-containing gas: Ammonia Gas (15 sccm to 130 sccm)

Pressure in processing chamber: 6.7 Pa to 25 Pa

First power: 2,000 W to 6, 000 W

Temperature of stage: 250º C. to 500º C.

### Process Conditions for Cleaning Process

Cleaning gas: Nitrogen trifluoride gas (300 sccm to 1,600 sccm)

Diluent gas: argon gas (300 sccm to 1,500 sccm)

Pressure in processing chamber: 20 Pa to 133 Pa

Second power: 2,000 W to 5,000 W

Temperature of stage: 250º C. to 500º C.

### Experimental Results

In the plasma processing apparatus 1 according to the embodiment, the dependency of the number of particles on the number of processed substrates W when the substrate processing method illustrated in FIG. 4 was repeatedly performed was confirmed (Example). In the Example, the first nozzle diameter D1 was 0.3 mm and the second nozzle diameter D2 was 0.5 mm. Process conditions for the cleaning process in the Example are as follows.

### Process Conditions for Cleaning Process

Cleaning gas: Nitrogen trifluoride gas (1,600 sccm)

Diluent gas: Argon gas (500sccm)

Pressure in processing chamber: 60 Pa

Second power: 4,000 W

Temperature of stage: 500º C.

For comparison, in the plasma processing apparatus 1 according to the embodiment, the second nozzle diameter D2 of the second gas nozzle 22 was changed to the same nozzle diameter as the first nozzle diameter D1 of the first gas nozzle 21, and then, similar to the Example, the dependency of the number of particles on the number of processed substrates W was confirmed (Comparative Example). In the Comparative Example, the first nozzle diameter D1 was 0.3 mm, and the second nozzle diameter D2 was 0.3 mm.

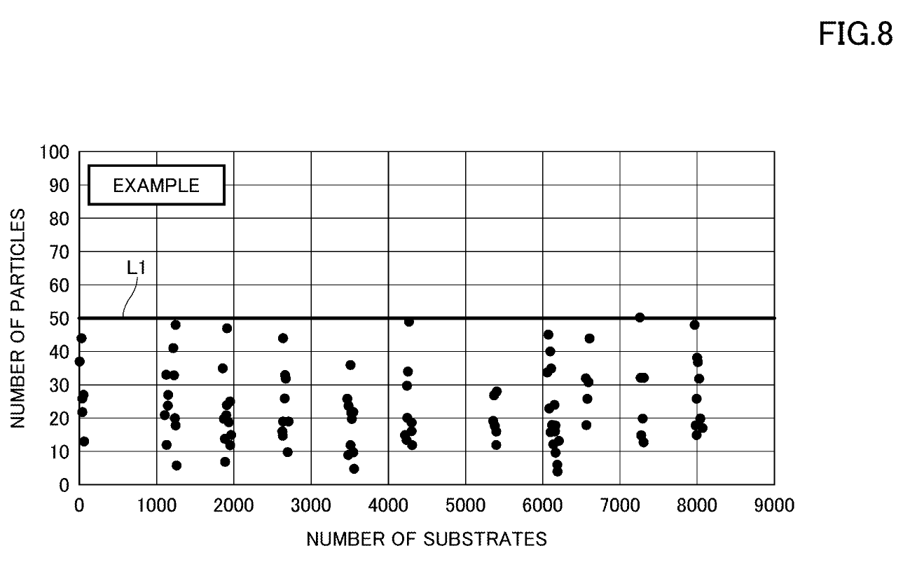

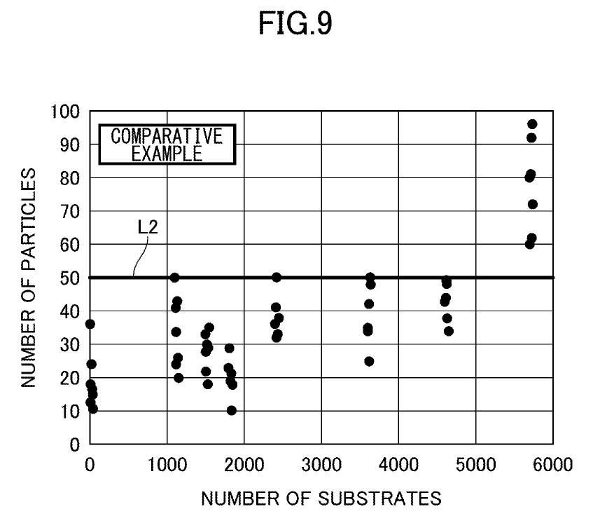

FIG. 8 is a graph illustrating the dependency of the number of particles on the number of processed substrates W in the Example. FIG. 9 is a graph illustrating the dependency of the number of particles on the number of processed substrates W in the Comparative Example. In each of FIGS. 8 and 9, the horizontal axis indicates the number of substrates, and the vertical axis indicates the number of particles on a substrate W. In FIGS. 8 and 9, straight lines L1 and L2 each indicate the permissible upper limit of the number of particles.

As illustrated in FIG. 8, in the Example, it can be seen that the number of particles is less than or equal to the permissible upper limit even when 8,000 substrates W are processed. Conversely, as illustrated in FIG. 9, in the Comparative Example, it can be seen that the number of particles is less than or equal to the permissible upper limit when the number of processed substrates W is 5,000 or less, but the number of particles is greater than the permissible upper limit when the number of processed substrates W exceeds 5,000. From these results, according to the Example, it was shown that generation of particles can be suppressed.

While certain embodiments have been described, these embodiments have been presented by way of example only, and are not intended to limit the scope of the present disclosure. Indeed, the embodiments described herein may be embodied in a variety of other forms. Furthermore, various omissions, substitutions and changes in the form of the embodiments described herein may be made without departing from the spirit of the present disclosure.

According to an embodiment of the present disclosure, adhesion of reaction by-products generated during a cleaning process to the interior of a processing chamber can be reduced, thereby suppressing generation of particles.

What is claimed is:

1. A cleaning method comprising:
supplying a cleaning gas into a processing chamber from a plurality of first gas nozzles provided through a top plate and each having a first nozzle diameter;
supplying a diluent gas into the processing chamber from a plurality of second gas nozzles provided through the top plate and each having a second nozzle diameter larger than the first nozzle diameter;
generating plasma from the cleaning gas and the diluent gas supplied into the processing chamber; and
performing cleaning by exposing an interior of the processing chamber to the plasma.

2. The cleaning method according to claim 1, further comprising:
supplying the cleaning gas from a first position via the plurality of first gas nozzles; and
supplying the diluent gas from a second position lower than the first position via the plurality of second gas nozzles.

3. The cleaning method according to claim 1, wherein the plurality of first gas nozzles and the plurality of second gas nozzles are alternately arranged on an identical circle.

4. The cleaning method according to claim 1, further comprising:
supplying the cleaning gas vertically downward via the plurality of first gas nozzles; and
supplying the diluent gas vertically downward via the plurality of the second gas nozzles.

5. The cleaning method according to claim 1, wherein a flow rate of the diluent gas is less than or equal to a flow rate of the cleaning gas.

6. The cleaning method according to claim 1, wherein
the first nozzle diameter is 0.3 mm or less, and
the second nozzle diameter is 0.5 mm or more and 2.0 mm or less.

7. The cleaning method according to claim 1, wherein the cleaning gas includes a halogen-containing gas.

8. The cleaning method according to claim 7, wherein the halogen-containing gas is nitrogen trifluoride gas, chlorine trifluoride gas, sulfur hexafluoride gas, tetrafluoromethane gas, or a combination of any of the foregoing.

9. The cleaning method according to claim 1, wherein the diluent gas is argon gas, helium gas, nitrogen gas, or a combination of any of the foregoing.

10. The cleaning method according to claim 1, wherein the plasma is microwave plasma.

11. A plasma processing apparatus comprising:
a processing chamber including a top plate;
a first gas nozzle provided through the top plate and configured to supply a cleaning gas into the processing chamber;
a second gas nozzle provided through the top plate and configured to supply a diluent gas into the processing chamber; and
a plasma source configured to generate plasma from the cleaning gas and the diluent gas supplied into the processing chamber, wherein
the first gas nozzle has a first nozzle diameter, and
the second gas nozzle has a second nozzle diameter larger than the first nozzle diameter.
